(19) United States
(12) Patent Application Publication
(10) Pub. No.: US 2012/0078553 A1
(43) Pub. Date: Mar. 29, 2012

(54) BATTERY CHARGE AMOUNT INCREASE FACILITY INFORMATION PROVISION DEVICE AND METHOD

(75) Inventors: Koichi Kuroda, Kanagawa (JP); Yasunori Maruyama, Kanagawa (JP); Kazuhito Katou, Kanagawa (JP); Ken Oizumi, Tokyo (JP)

(73) Assignee: Nissan Motor Co., Ltd.

(21) Appl. No.: 13/375,998

(22) PCT Filed: Jun. 4, 2010
(86) PCT No.: PCT/JP2010/059886

§ 371 Date: Dec. 2, 2011

(30) Foreign Application Priority Data
Jun. 26, 2009 (JP) 2009-152056
Mar. 15, 2010 (JP) 2010-057683

(51) Int. Cl. G01R 31/36; G06F 19/00

(52) U.S. Cl. 702/63

(57) ABSTRACT

A battery charge amount increase facility information provision device provides information relating to a battery charge amount increase facility to a vehicle installed with a battery (60) that is charged using an external power supply. The device includes a current position sensor (51) which detects a current position of the vehicle, a charge amount sensor (52) which detects a battery charge amount (SOC), a database (20) which registers the formation relating to the battery charge amount increase facility, and a controller (10). The controller (10) registers the current position of the vehicle in the database (20) as a location of a battery charge amount increase facility when the SOC has increased under a predetermined condition (S113). As a result, an amount of information relating to the locations of usable battery charge amount increase facilities is increased.

### FIELD OF THE INVENTION

This invention relates to technology for providing a driver of an electric vehicle with information on nearby battery charge amount increase facilities.

### BACKGROUND OF THE INVENTION

JPH09-210702A, published by the Japan Patent Office in 1997, proposes an information provision device that informs a driver of a battery charge amount increase facility existing on the periphery of a current position of an electric vehicle.

### SUMMARY OF THE INVENTION

In this conventional technique, the driver is provided with information registered in advance in the information provision device. In other words, information relating to battery charge amount increase facilities other than the battery charge amount increase facilities registered in advance, such as new battery charge amount increase facilities installed after information registration, cannot be provided.

It is therefore an object of this invention to inform a driver of a larger number of locations of usable battery charge amount increase facilities.

In order to achieve the above object, this invention provides a battery charge amount increase facility information provision device for providing information relating to a battery charge amount increase facility to a vehicle installed with a battery that is charged using an external power supply. The battery charge amount increase facility includes at least one of a battery charging facility and a battery replacement facility.

The device comprises a current position sensor that detects a current position of the vehicle, a charge amount sensor that detects a battery charge amount, a database which registers the information relating to the battery charge amount increase facility, and a programmable controller.

The programmable controller is programmed to determine whether or not the battery charge amount has increased under a predetermined condition, and register the current position of the vehicle in the database as a location of a battery charge amount increase facility when the battery charge amount has increased under the predetermined condition.

This invention also provides a battery charge amount increase facility information provision method comprising detecting a current position of the vehicle, detecting a battery charge amount, determining whether or not the battery charge amount has increased under a predetermined condition, and registering the current position of the vehicle in the database as a location of a battery charge amount increase facility when the battery charge amount has increased under the predetermined condition.

The details as well as other features and advantages of this invention are set forth in the remainder of the specification and are shown in the accompanying drawings.

### BRIEF DESCRIPTION OF THE DRAWINGS

FIG. 1 is a block diagram showing the constitution of a battery charge amount increase facility information provision device according to this invention.

FIG. 2 is a flowchart showing a battery charge amount increase point registration routine executed by a navigation controller according to this invention.

FIG. 3 is a diagram showing characteristics of a charging output table stored in the navigation controller.

FIG. 4 is a diagram showing a capture screen of a display during display of a dialog inquiring whether or not a battery charge amount increase point is to be registered.

FIG. 5 is a diagram showing a capture screen of the display for inputting detailed information relating to a battery charge amount increase point.

FIG. 6 is similar to FIG. 5, but shows a case in which the charging output is “rapid charging”.

FIG. 7 is similar to FIG. 5, but shows a case in which the charging output is “200V”.

FIG. 8 is similar to FIG. 5, but shows a case in which the charging output is “100V”.

FIG. 9 is a flowchart showing a battery charge amount increase point registration routine executed by a navigation controller according to a second embodiment of this invention.

FIG. 10 is a flowchart showing a battery charge amount increase point registration routine executed by a navigation controller according to a third embodiment of this invention.

FIG. 11 is a block diagram showing the constitution of a battery charge amount increase facility information provision device according to a fourth embodiment of this invention.

FIG. 12 is a flowchart showing a battery charge amount increase point registration routine executed by a navigation controller according to the fourth embodiment of this invention.

FIG. 13 is a block diagram showing the constitution of a battery charge amount increase facility information provision device according to a fifth embodiment of this invention.

### DESCRIPTION OF THE PREFERRED EMBODIMENTS

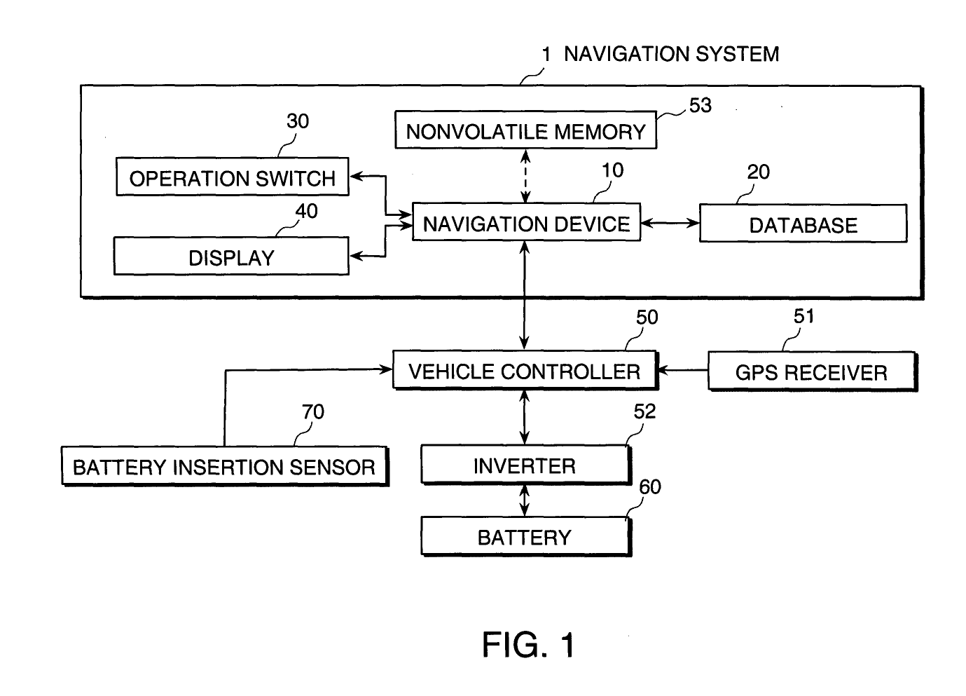

Referring to FIG. 1 of the drawings, a battery charge amount increase facility information provision device according to this invention includes a navigation system 1 installed in an electric vehicle. The navigation system 1 includes a navigation controller 10, a database 20, an operating switch 30, and a display 40. These elements are connected by a vehicle-mounted local area network (LAN) such as a controller area network (CAN) in order to exchange information with each other.

The electric vehicle includes a battery 60 serving as a travel drive source. The battery 60 is constituted by a lithium ion battery or a nickel hydrogen battery, for example. It should be noted, however, that this invention is not limited by the types of the battery 60. The battery 60 is installed in the vehicle in an arbitrarily replaceable state.

The database 20 is constituted by a writable storage medium storing map information and road information used by the navigation system 1. The road information stored in the database 20 is constituted by nodes and complementary points indicating road shapes, a collection of vector data represented by lines connecting the nodes and complementary points, and battery charge amount increase point information stored together with latitude/longitude information.

Road attribute data are included in the road information. For example, latitude and longitude are included in the nodes and complementary points as attribute data together with road curvature information indicating a road curvature at the nodes and complementary points. Road type and road width information is included as attribute data in the lines connecting the nodes and complementary points. The information is stored together with an icon indicating the type of the information.

The information stored in the database 20 is not limited to the information described above, and any other information that is unique to a node or a complementary point may be added. In the navigation system 1, a facility having usable charging equipment and a facility supplying replacement batteries are included in the information. Two types of battery charge amount increase points are included, namely battery charge amount increase points registered in the database 20 in advance and new battery charge amount increase points registered additionally during a battery charge amount increase point registration routine executed by the navigation controller 10.

Examples of a new, additionally registered battery charge amount increase point include general-purpose charging equipment at a newly installed facility or the like, and a charging power supply that can be used by a specific user only, such as a household power supply for individual use.

The operating switch 30 is operated by a driver or a passenger to realize various functions of the navigation system 1, for example to set a destination. Various switch types provided on an operating panel or an input interface such as a touch panel screen may be used as the operating switch 30.

The display 40 is constituted by a CRT monitor or a liquid crystal monitor, for example. The display 40 displays information included in an image signal transmitted from the navigation controller 10 on a screen on the basis of the image signal. A user is provided with information for realizing the various functions of the navigation system 1. More specifically, information indicating a current vehicle position, map information and place name information relating to the vehicle periphery, the aforementioned geographical point information relating to a battery charge amount increase point, a route to the set destination, and so on are displayed.

The navigation controller 10 is constituted by a microcomputer comprising a central processing unit (CPU), a read-only memory (ROM), a random access memory (RAM), and an input/output interface (I/O interface). The navigation controller 10 may be constituted by a plurality of microcomputers.

The navigation controller 10 is connected to a vehicle controller 50 by a vehicle-mounted LAN to be capable of obtaining information relating to the vehicle. The vehicle controller 50 performs operation control of an electric motor serving as a travel power source of the vehicle, control of various accessories, and charging control of the battery 60.

The vehicle controller 50 is constituted by a microcomputer comprising a central processing unit (CPU), a read-only memory (ROM), a random access memory (RAM), and an input/output interface (I/O interface). The vehicle controller 50 may be constituted by a plurality of microcomputers. Alternatively, the navigation controller 10 and the vehicle controller 50 may be constituted by a single microcomputer.

Various control machines, information obtaining devices and sensors, such as an inverter 52 that controls charging/discharging of the battery 60, a receiver 51 of a global positioning system (GPS), a vehicle speed sensor, an acceleration sensor, an inhibitor switch that detects a shift lever position, and a parking brake switch that detects an ON/OFF state of a parking brake, are connected to the vehicle controller 50. The vehicle controller 50 is also connected to the battery 60 and a battery insertion sensor 70. The vehicle controller 50 controls charging/discharging of the battery 60 via the inverter 52. The inverter 52 inputs information relating to a state of charge (SOC) of the battery 60 into the vehicle controller 50. The battery insertion sensor 70 inputs information relating to whether or not the battery 60 has been replaced into the vehicle controller 50.

In this embodiment, the navigation system 1, the vehicle controller 50 that provides the navigation system 1 with various operation information, the battery insertion sensor 70, the inverter 52, and the GPS receiver 51 together constitute a battery charge amount increase facility information provision device.

The navigation controller 10 includes the following functions for additionally registering a new battery charge amount increase point in the database 20.

The navigation controller 10 includes a vehicle stop determination function to determine whether or not the vehicle is stationary, a position detection function to detect the position of the vehicle, a SOC detection function to detect the SOC of the battery 60, a pre-registration determination function to determine whether or not the current vehicle position matches a battery charge amount increase point registered in the database 20, an SOC increase determination function to determine whether or not the SOC of the battery 60 has increased, an SOC increase point setting function to set the vehicle position at the point where the SOC of the battery 60 is determined to have increased as an SOC increase point, a battery replacement determination function to determine whether or not the battery 60 has been replaced, a charging output estimation function to estimate a charging output of a charging power supply at the SOC increase point, and a registration function to register the SOC increase point in the database 20 as a battery charge amount increase point.

The vehicle stop determination function is used to obtain information relating to a vehicle speed, a shift lever position, and an operating state of the parking brake from the vehicle controller 50 and determine whether or not the vehicle is stationary. More specifically, when all or at least two of the following conditions are established, the vehicle is determined to be stationary: the vehicle speed is zero; the shift lever is in a parking range or a neutral range; and the parking brake is ON. When the vehicle is determined to be stationary, the vehicle stop determination function determines whether or not the stationary state has continued for at least a predetermined time t. The predetermined time t is set at a sufficient length to determine that the vehicle has stopped in order to charge or replace the battery 60, or in other words a time that is sufficiently long to exclude brief stoppages for stoplights or the like, for example, 2 minutes.

The position detection function is used to detect the latitude/longitude of the current vehicle position and a vehicle advancement direction on the basis of information from the GPS receiver 51, the vehicle speed sensor, and the acceleration sensor, which is obtained via the vehicle controller 50. There are no particular limitations on a detection interval, but an interval of 5 Hertz (Hz), for example, may be used.

The SOC detection function is used to detect the SOC of the battery 60 via the vehicle controller 50. The SOC detection function constantly monitors the SOC and stores a monitoring result over a period corresponding at least to a period required to charge the battery 60.

The pre-registration determination function is used to determine whether or not the current vehicle position matches a battery charge amount increase point registered in the database 20 on the basis of the battery charge amount increase point information registered in the database 20 and the vehicle position information detected by the position detection function. In a specific determination, a radius range corresponding to an error is applied, and a determination is made as to whether or not the vehicle position is within the radius range corresponding to the error from a battery charge amount increase point.

The SOC increase determination function is used to determine whether or not the SOC of the battery 60 has increased from the SOC of the battery 60 detected by the SOC detection function when the pre-registration determination function determines that the current vehicle position does not match a battery charge amount increase point registered in the database 20. More simply, the SOC increase determination function determines whether or not the battery 60 has been charged or replaced. Specifically, the SOC increase determination function compares the SOC of the battery 60 at the point where stoppage of the vehicle was detected by the vehicle stop determination function with the SOC of the battery 60 following the elapse of the predetermined time t following the vehicle stoppage, and when the latter is greater than the former, the SOC increase determination function determines that the battery 60 has been charged or replaced.

The determination as to whether or not the SOC of the battery 60 has increased is preferably made in consideration of a preset error range accounting for variable factors such as temperature conditions.

The determination of the SOC increase determination function is made only when the pre-registration determination function determines that the current vehicle position does not match a battery charge amount increase point registered in the database 20. The reason for this is that when the current vehicle position does match a battery charge amount increase point registered in the database 20, the current vehicle position does not need to be registered in the database 20 as a battery charge amount increase point.

When the SOC increase determination function determines that the SOC of the battery 60 has increased, or in other words that the battery 60 has been charged or replaced, the SOC increase point setting function obtains the vehicle position detected by the position detection function and sets the obtained vehicle position as the SOC increase point.

The battery replacement detection function is used to obtain a signal output by the battery insertion sensor 70 from the vehicle controller 50 and determine whether or not the battery 60 has been replaced.

The charging output estimation function is used to estimate the charging output of the charging power supply at the SOC increase point set by the SOC increase point setting function. More specifically, when the SOC increase point setting function sets the SOC increase point, the charging output estimation function calculates a charge time T required to charge the battery 60. The charging output estimation function then calculates a SOC increase S achieved during the charge time T from the SOC of the battery 60 detected by the SOC detection function. The charging output estimation function then estimates the charging output of the charging power supply at the SOC increase point from the calculated charge time T and SOC increase S.

The charge time T may be obtained using a method of calculating the charge time T in which a charging start timing and a charging end timing of the battery 60 are obtained either directly from a charging device for charging the battery 60, such as the inverter 52, or via the vehicle controller 50, and a time from the start to the end of charging is counted.

When the charging start timing and charging end timing cannot be obtained, the charging output may be calculated without using the charge time T from the predetermined time t and a difference between the SOC at the point where vehicle stoppage was detected by the vehicle stop determination function and the SOC following the elapse of the predetermined time t.

It should be noted, however, that when replacement of the battery 60 is detected by the battery replacement detection function, the charging output estimation function does not estimate the charging output.

The registration function displays a question inquiring whether or not the SOC increase point is to be set as a charging point or a replacement point on the display 40 when the SOC increase point setting function sets the SOC increase point. When the driver or passenger indicates that the SOC increase point is to be set as a charging point via the operating switch 30, the registration function registers the SOC increase point relating to the question in the database 20 as a charging point.

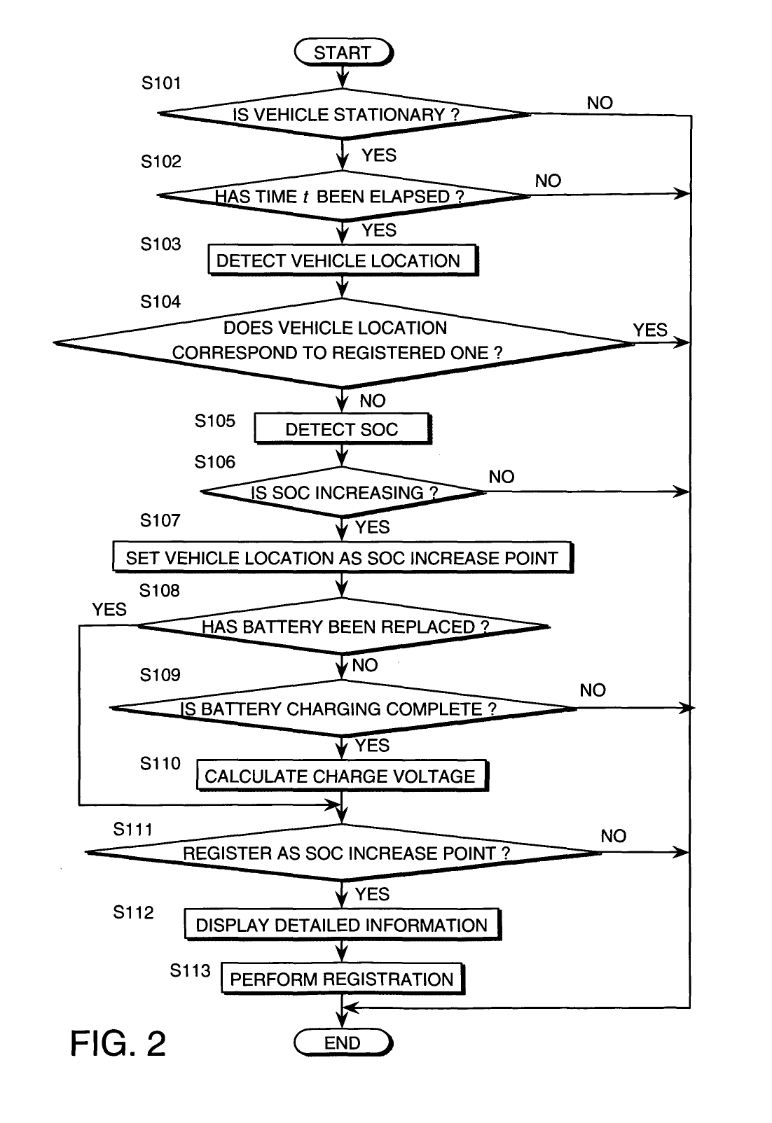

Referring to FIG. 2, a battery battery charge amount increase point registration routine executed by the navigation controller 10 to realize the above functions will now be described.

This routine is executed repeatedly while operating power is supplied to the navigation system 1, regardless of the state of the vehicle. More specifically, execution of the next routine begins every time the routine reaches the end.

In a step S101, the navigation controller 10 uses the vehicle stop determination function to determine whether or not the vehicle is stationary. When the vehicle is determined to be stationary, the navigation controller 10 performs the processing of a step S102. When it is determined that the vehicle is not stationary, the navigation controller 10 immediately terminates the routine. In other words, the processing of the step S102 onward is performed only when the vehicle is determined to be stationary.

In the step S102, the navigation controller 10 determines whether or not the predetermined time t has elapsed following the determination that the vehicle is stationary. When the determination is affirmative, the navigation controller 10 performs the processing of a step S103. When the determination is negative, the navigation controller 10 immediately terminates the routine.

In the step S103, the navigation controller 10 uses the position detection function to detect the current position of the vehicle on the basis of information obtained from the vehicle controller 50.

In a step S104, the navigation controller 10 uses the pre-registration determination function to determine whether or not the current vehicle position matches a battery charge amount increase point registered in the database 20. When the current vehicle position does not match a battery charge amount increase point registered in the database 20, the navigation controller 10 performs the processing of a step S105. When the current vehicle position matches a battery charge amount increase point registered in the database 20, on the other hand, the navigation controller 10 immediately terminates the routine. As a result of this processing, a memory capacity of the database 20 can be saved and a situation in which an identical battery charge amount increase point is registered in duplicate can be prevented.

In the step S105, the navigation controller 10 uses the SOC detection function to detect a latest SOC of the battery 60 via the vehicle controller 50.

In a step S106, the navigation controller 10 determines whether or not the SOC of the battery 60 has increased by comparing the SOC of the battery 60 following the elapse of the predetermined time t after the vehicle becomes stationary with the latest SOC detected in the step S105. It should be noted that in a case where the step S106 is executed immediately after S102 becomes affirmative, or in other words immediately after the elapse of the predetermined time t following vehicle stoppage, the former SOC and the latter SOC take identical values. In this case, the determination is negative.

When the determination of the step S106 is negative, the navigation controller 10 immediately terminates the routine. The reason for this is that if the SOC has not increased, charging or replacement has not been performed, and therefore the current position of the stationary vehicle does not correspond to a battery charge amount increase point. When the determination of the step S106 is affirmative, the navigation controller 10 uses the SOC increase point setting function in a step S107 to set the current vehicle position as a SOC increase point.

In a step S108, the navigation controller 10 uses the battery replacement detection function to determine whether or not the battery 60 has been replaced. When the battery 60 has not been replaced, the navigation controller 10 determines that the SOC increase point includes a charging power supply and therefore performs the processing of a step S109. When replacement of the battery 60 is detected, on the other hand, the navigation controller 10 determines that a battery replacement facility exists at the SOC increase point, and therefore skips the processing of the step S109 and a step S110 and performs the processing of a step S111.

In the step S109, the navigation controller 10 determines whether or not charging of the battery 60 is compete via the vehicle controller 50. When the determination is negative, this means that the battery 60 is still being charged. In this case, the navigation controller 10 immediately terminates the routine. When the determination is affirmative, the navigation controller 10 uses the charging output estimation function in the step S110 to calculate the charging output used to charge the battery 60.

More specifically, first, the navigation controller 10 detects the charge time T and the variation S in the SOC of the battery 60 during the charge time T via the vehicle controller 50.

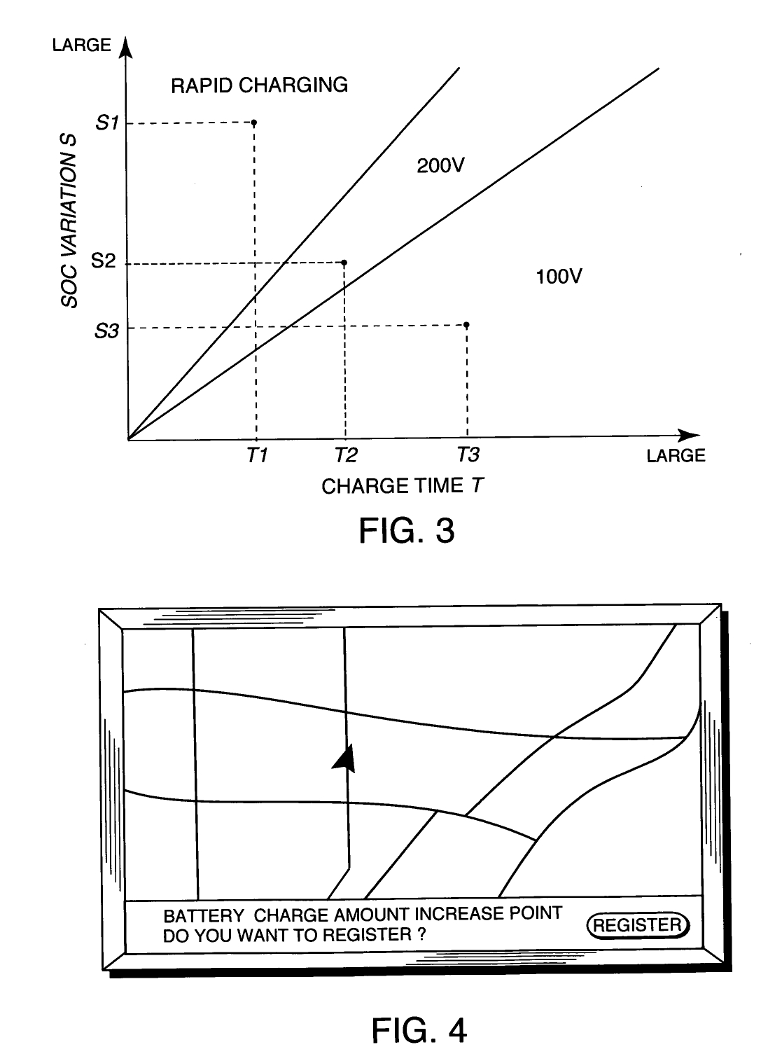

Next, the navigation controller 10 estimates the charging output from the charge time T and the SOC variation S by referring to a map having the content shown in FIG. 3, which is stored in the ROM in advance. For example, when the charge time is T1 and the SOC variation is S1, the charging output is determined to correspond to “rapid charging”. When the charge time is T2 and the SOC variation is S2, the charging output is determined to correspond to “200V”. When the charge time is T3 and the SOC variation is S3, the charging output is determined to correspond to “100V”. Needless to say, the charging output may be calculated from the charge time T and the SOC variation S using another method.

Next, in the step S111, the navigation controller 10 displays a question on the display 40 inquiring whether or not the current position is to be registered as a battery charge amount increase point.

Referring to FIG. 4, the question is preferably displayed on the display 40 together with a display of the current position.

If a registration button has not been operated after a fixed time period, it is determined that a registration operation has not been performed in response to the question. When a registration operation is not performed in response to the question for the fixed time period, the navigation controller 10 terminates the routine.

When the registration operation is performed in response to the question within the fixed time period, on the other hand, the navigation controller 10 performs the processing of a step S112. The driver or passenger performs the registration operation by touching a registration button displayed on the screen in FIG. 4. In the step S112, the navigation controller 10 uses a control function to display detailed information relating to the battery charge amount increase point to be registered on the display 40.

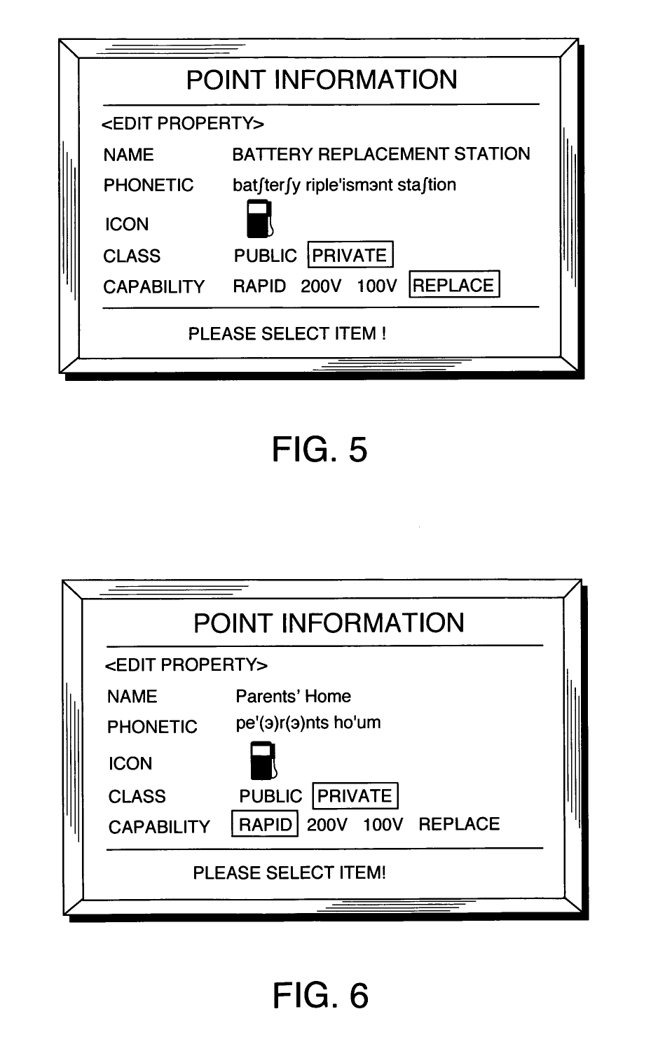

Referring to FIG. 5, detailed information constituted by (1) a name of the battery charge amount increase point, (2) the pronunciation of the name, (3) an icon to be displayed on a map, (4) a classification indicating whether the battery charge amount increase point is public or private, and (5) a battery charge amount increase capability is displayed on the display 40. Of this information, information (1) to (4) is either input by the driver or passenger via the operating switch 30 or selected and confirmed on the screen. As regards information (5), on the other hand, when the determination of the step S108 is affirmative, “REPLACE” is displayed the capability section, as shown in the figure, and when the determination of the step S108 is negative, the calculation result of the step S110 is displayed. It should be noted that a cautioning voice is preferably output to encourage the driver or passenger to input the information items (1) to (4).

Referring to FIG. 6, when it is determined in the step S109 that the charging output of the charging power supply at the SOC increase point corresponds to rapid charging, “Rapid charging” is displayed in bold in the charging input section of the display 40.

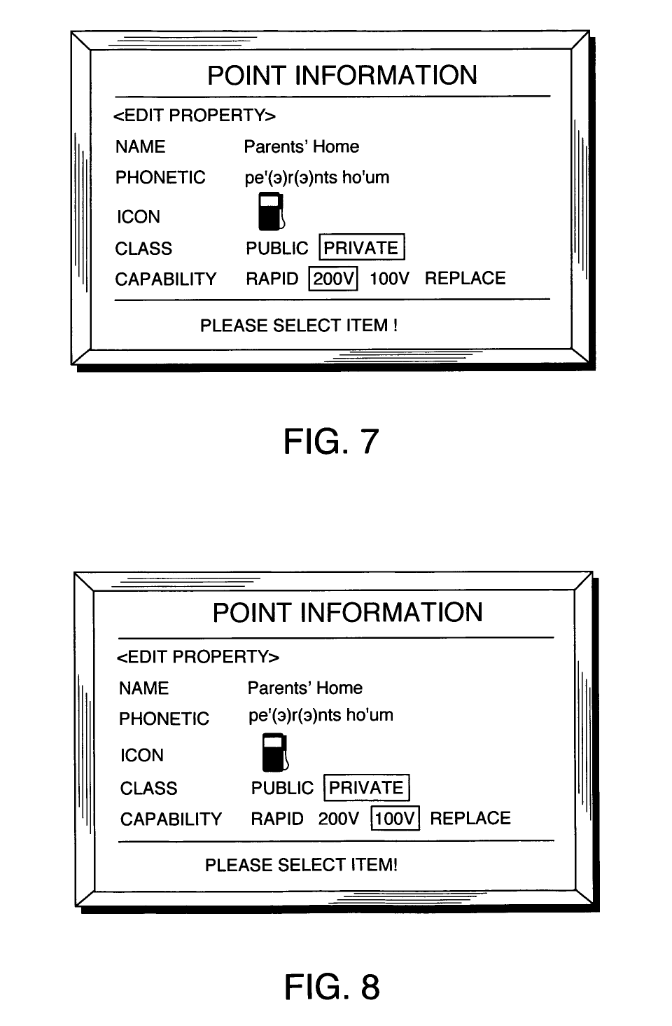

Referring to FIG. 7, when it is determined in the step S109 that the charging output of the charging power supply at the SOC increase point corresponds to 200V, “200V” is displayed in bold in the charging input section of the display 40.

Referring to FIG. 8, when it is determined in the step S109 that the charging output of the charging power supply at the SOC increase point corresponds to 100V, “100V” is displayed in bold in the charging input section of the display 40.

When the processing of the step S112 is complete, the navigation controller 10 registers the information relating to the battery charge amount increase point in a step S113, including the detailed information input in the step S112, in the database 20. Following the processing of the step S113, the navigation controller 10 terminates the routine.

The battery charge amount increase point registered additionally in the database 20 as described above is used in the following manner.

When the driver or passenger operates the operating switch 30 to search for a battery charge amount increase point in the vicinity of the current vehicle position, the additionally registered battery charge amount increase point is displayed on the display 40 together with the battery charge amount increase points registered in the database 20 in advance. As a result, the number of usable battery charge amount increase points registered in the database 20 can be increased every time the battery 60 is charged.

Further, a possible travel distance of the vehicle can be calculated from the SOC of the battery 60 detected by the SOC detection function of the navigation controller 10, and therefore the likelihood that no battery charge amount increase points exist within a possible travel distance range can be predicted. When it is predicted that no battery charge amount increase points are likely to exist, a warning is preferably displayed on the display 40. The additionally registered battery charge amount increase point is taken into account during the prediction, and therefore the likelihood that no battery charge amount increase points exist can be reduced.

In the navigation system 1, a battery charge amount increase point is registered additionally in the database 20 on the basis of an actual charging or replacing operation. Therefore, additional battery charge amount increase point registration can be performed easily, and only reliable information is additionally registered.

Moreover, by providing the charging output section in the additional registration information, the driver or passenger can select a charging point by predicting the required charge time in advance.

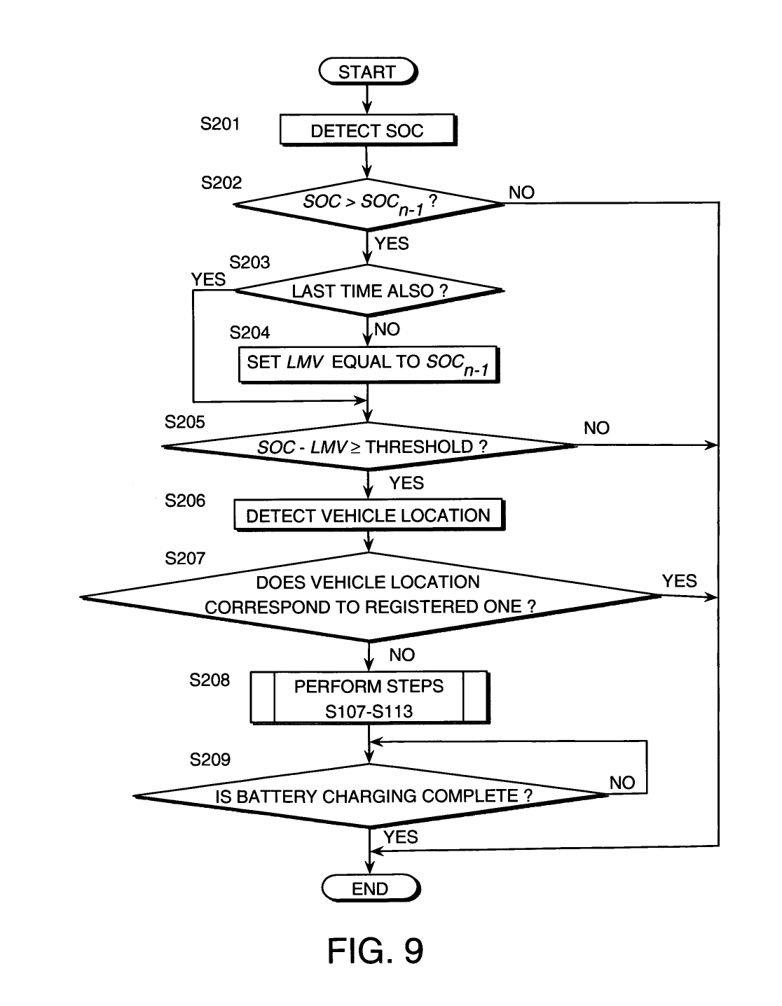

Referring to FIG. 9, a second embodiment of this invention will be described.

This embodiment differs from the first embodiment in the following point. The battery 60 installed in the vehicle is also charged through regenerative power generation accompanying vehicle braking. Therefore, when determining a charging point, measures must be taken to ensure that charging at a charging facility is not mistaken for charging performed through regenerative power generation. In the first embodiment, erroneous determinations are prevented simply by not determining a charging point when the vehicle is determined not to be stationary.

In the second embodiment, on the other hand, the stationary state of the vehicle is not determined, and instead, an essential condition for determining a charging point is that the increase in the SOC exceeds a predetermined threshold. The SOC increase achieved by charging through regenerative power generation is small, and therefore charging through regenerative power generation can be excluded from the charging point determination by comparing the SOC increase with the threshold.

For this purpose, the navigation controller 10 according to this embodiment includes a minimum value setting function and an SOC increase determination function instead of the vehicle stop determination function, and executes a battery charge amount increase point registration routine shown in FIG. 9 instead of the battery charge amount increase point registration routine shown in FIG. 2. All other constitutional requirements of the navigation controller 10 are identical to those of the first embodiment. Further, the execution conditions of the battery charge amount increase point registration routine shown in FIG. 9 are identical to the execution conditions of the battery charge amount increase point registration routine shown in FIG. 2.

In a step S201, the navigation controller 10 uses the SOC detection function to detect the SOC of the battery 60 via the vehicle controller 50.

In a step S202, the navigation controller 10 determines whether or not the SOC is larger than a previous value SOCₙ₋₁ of the SOC detected during the previous execution of the routine, or in other words whether or not the SOC has increased. As the vehicle travels, the SOC gradually decreases. Therefore, the SOC exceeds the previous value SOCₙ₋₁ only when the battery 60 has been charged. When the SOC is not larger than the previous value SOCₙ₋₁, the battery 60 has not been charged, and therefore the navigation controller 10 immediately terminates the routine. When the SOC is larger than the previous value SOCₙ₋₁, the navigation controller 10 determines in a step S203 whether or not a similar determination result was obtained during the previous execution of the subroutine.

When the determination of the step S203 is affirmative, this means that the SOC is continuing to increase. In this case, the navigation controller 10 performs the processing of a step S205. When the determination of the step S203 is negative, this means that the SOC has begun to increase following the previous execution of the routine. In this case, the navigation controller 10 sets the previous value SOCₙ₋₁ at a minimum value LMV in a step S204 and then performs the processing of the step S205. The processing of the steps S202 to S204 corresponds to the minimum value setting function.

In the step S205, the navigation controller 10 uses the SOC increase determination function to determine whether or not a difference between the SOC and the minimum value LMV is larger than a threshold. Here, the threshold is set at a larger value than a charge amount applied to the battery 60 by regenerative braking. When, in accordance with this setting, the difference between the SOC and the minimum value LMV is larger than the threshold, it may be determined that the SOC increase is due to charging of the battery 60 at a charging facility rather than charging of the battery 60 by regenerative braking.

When the determination of the step S205 is negative, the navigation controller 10 immediately terminates the routine. When the determination of the step S205 is affirmative, the navigation controller 10 uses the position detection function in a step S206 to detect the current position of the vehicle on the basis of the information obtained from the vehicle controller 50, similarly to the step S103.

Next, in a step S207, the navigation controller 10 uses the pre-registration determination function to determine whether or not the current vehicle position matches a battery charge amount increase point registered in the database 20, similarly to the step S104.

When the determination of the step S207 is affirmative, the navigation controller 10 immediately terminates the routine. When the determination of the step S207 is negative, the navigation controller 10 performs the processing of the steps S107-S113 of the first embodiment to register the current vehicle position in the database 20.

Following the processing of the step S113, the navigation controller 10 determines in a step S209 whether or not charging of the battery 60 is complete. For example, the SOC is compared to the previous value SOCₙ₋₁, similarly to the step S202, and when the SOC no longer exceeds the previous value SOCₙ₋₁, it may be determined that charging of the battery 60 is complete. When it is determined that charging of the battery 60 is complete, the navigation controller 10 terminates the routine. When charging of the battery 60 is not complete, the navigation controller 10 waits until charging of the battery 60 is complete and then terminates the routine.

In this embodiment also, similarly to the first embodiment, the number of usable battery charge amount increase points registered in the database 20 can be increased every time the battery 60 is charged.

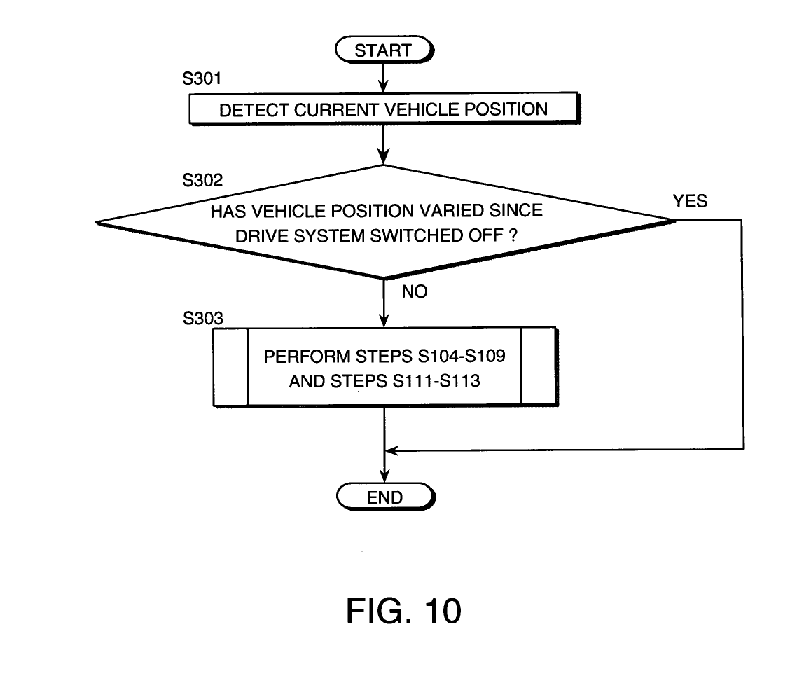

Referring to FIG. 10, a third embodiment of this invention will be described.

The navigation controller 10 according to this embodiment executes a battery charge amount increase point registration routine shown in FIG. 10 instead of the battery charge amount increase point registration routine according to the first embodiment, shown in FIG. 2.

An execution condition of this routine differs from that of the routine shown in FIG. 2. The routine of FIG. 2 is executed iteratively while the navigation system 1 is operative, whereas this routine is executed only once immediately after a switch of a drive system of the electric vehicle is switched ON. It should be noted that the navigation system 1 is assumed always to be operative when the switch of the drive system is switched.

The navigation controller 10 according to this embodiment includes a position variation detection function instead of the vehicle stop determination function of the first embodiment. The position variation detection function is used to determine whether or not the vehicle position has varied when the drive system switch of the electric vehicle is switched OFF and when the switch is switched ON again. For this purpose, the navigation controller 10 stores the vehicle position on the basis of information from the GPS receiver 51, which is obtained from the vehicle controller 50 at the point where the drive system switch of the electric vehicle is switched OFF.

Further, the SOC increase determination function determines whether or not the SOC has increased from the point at which the drive system switch of the electric vehicle is switched OFF to the point at which the drive system switch is switched ON again. For this purpose, the navigation controller 10 stores the SOC obtained from the vehicle controller 50 at the point where the drive system switch of the electric vehicle is switched OFF.

As shown in FIG. 1, the navigation controller 10 according to this embodiment includes a non-volatile memory 53 to ensure that information relating to the vehicle position and the SOC is not lost even when a supply of operating power to the navigation controller 10 is interrupted. An Electronically Erasable and Programmable Read Only Memory (EEPROM), for example, may be used as the non-volatile memory 53.

Referring to FIG. 10, in a step S301, the navigation controller 10 uses the position detection function to detect the current position of the vehicle on the basis of the information obtained from the vehicle controller 50, similarly to the step S103 of the first embodiment.

Next, in a step S302, the navigation controller 10 uses the position variation detection function to determine whether or not position variation has occurred by comparing the vehicle position at the point where the drive system switch was turned OFF with the current vehicle position. When it is determined that position variation has occurred, the navigation controller 10 immediately terminates the routine.

When it is determined that position variation has not occurred, the navigation controller 10 performs the processing of the steps S104-S109 and the steps S111-S113 of the first embodiment in a step S303.

It should be noted that the determination of the step S106 as to whether or not the SOC has increased is made by comparing the SOC stored at the point where the drive system switch of the electric vehicle was switched OFF with the SOC detected in the step S105 of the current execution of the routine.

Further, in this embodiment, the charge time T is not detected, and therefore the processing of the step S110 is omitted. Moreover, of the information displayed on the display 40 in the step S112, only a charging facility and a battery replacement facility are displayed in the capability section (5).

By executing the above routine, the battery charge amount increase point is determined only when the drive system switch of the electric vehicle is switched from OFF to ON. If the SOC increases while the drive system switch is OFF, this means that the battery 60 has been charged or replaced in the meantime.

On the other hand, if the vehicle position varies during this time, this indicates that the vehicle has been moved by a tow truck or other means. In this case, the battery charge amount increase point is not registered.

In this embodiment also, similarly to the first embodiment, the number of usable battery charge amount increase points registered in the database 20 can be increased every time the battery 60 is charged.

Furthermore, the navigation controller 10 according to this embodiment executes the battery charge amount increase point registration routine only once, immediately after the drive system switch is switched ON, and does not execute the routine as the electric vehicle travels. Hence, in comparison with the first and second embodiments, a load of the navigation controller 10 can be reduced.

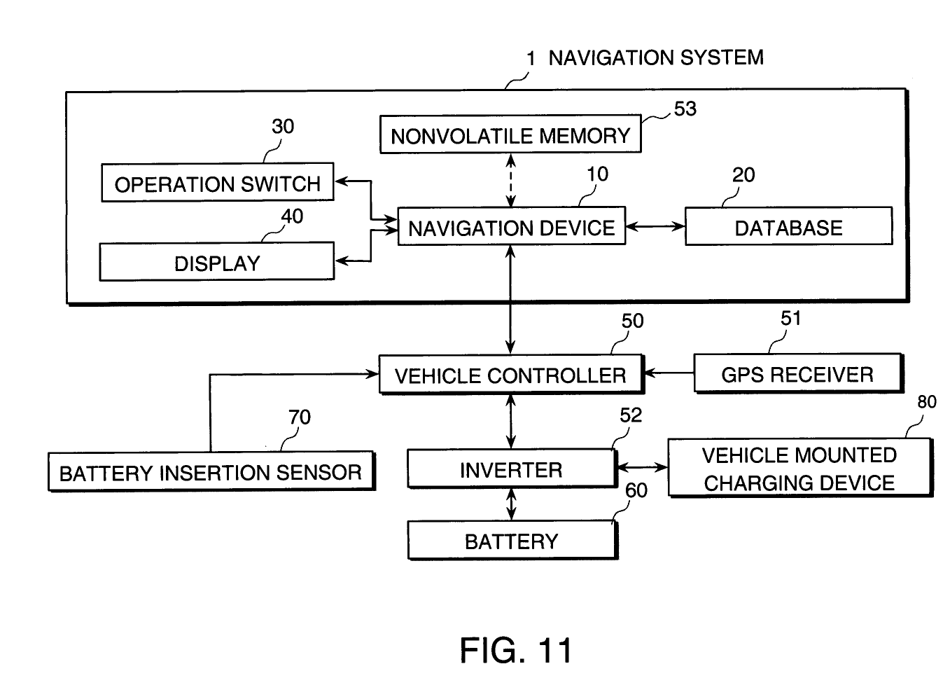

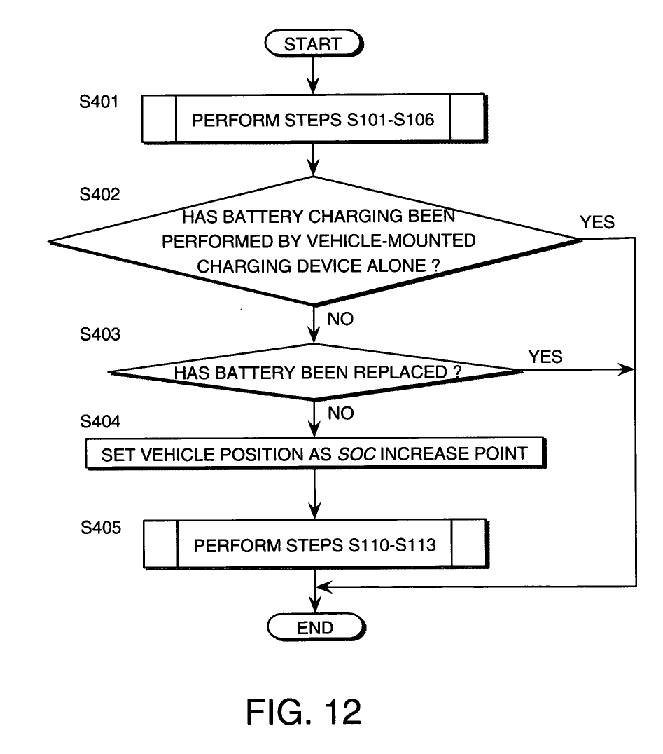

Referring to FIGS. 11 and 12, a fourth embodiment of this invention will be described.

Referring to FIG. 11, the battery charge amount increase facility information provision device according to this embodiment differs from those of the other embodiments in that it is applied only to an electric vehicle having a vehicle-mounted charging device 80.

The vehicle-mounted charging device 80 is a device that can charge the battery 60 independently of an external charging facility. For example, a solar cell installed in the electric vehicle or a battery charging engine generator, also known as a range extender, corresponds to the vehicle-mounted charging device 80. In a hybrid drive electric vehicle, an internal combustion engine and a generator correspond to the vehicle-mounted charging device 80.

In this type of electric vehicle, a determination must be made as to whether charging has been performed by the vehicle-mounted charging device 80 in order to identify the charging point of the battery 60. Therefore, the navigation controller 10 according to this embodiment includes an in-vehicle charging determination function that performs this determination.

When the SOC increase determination function determines that the SOC of the battery 60 has increased, the in-vehicle charging determination function determines whether or not the SOC increase is due to the vehicle-mounted charging device 80 alone. More specifically, information relating to a total amount of power input into the battery 60 and information relating to an amount of power input into the battery 60 from the vehicle-mounted charging device 80 are obtained from the vehicle controller 50. When the total amount of power input into the battery 60 is equal to the amount of power input into the battery 60 from the vehicle-mounted charging device 80, it is determined that the battery 60 has been charged by the vehicle-mounted charging device 80 alone.

When it is determined that the battery 60 has been charged by the vehicle-mounted charging device 80 alone, the navigation controller 10 does not perform the charging point determination. The navigation controller 10 performs the charging point determination only when it is determined that the battery 60 has not been charged by the vehicle-mounted charging device 80 alone.

Referring to FIG. 12, a battery charge amount increase point registration routine including the above process, which is executed by the navigation controller 10, will be described. This routine is executed under identical execution conditions to the routine according to the first embodiment, shown in FIG. 2.

First, in a step S401, the navigation controller 10 executes the processing of the steps S101-S106 of the first embodiment. It should be noted that when the determination of either the step S101 or the step S106 is negative and the determination of the step S104 is affirmative, the navigation controller 10 immediately terminates the routine, similarly to the first embodiment.

The navigation controller 10 performs the processing of a step S402 onward only when the determination of the step S106 is affirmative.

In the step S402, the navigation controller 10 uses the in-vehicle charging determination function to determine whether or not the increase in the SOC of the battery 60 is due to the vehicle-mounted charging device 80 alone.

When it is determined in the step S402 that the SOC increase is due to the vehicle-mounted charging device 80 alone, the navigation controller 10 immediately terminates the routine. When it is determined that the SOC increase is not due to the vehicle-mounted charging device 80 alone, on the other hand, the navigation controller 10 determines in a step S403 whether or not the battery 60 has been replaced, similarly to the step S108 of the first embodiment. When the battery has been replaced, the navigation controller 10 immediately terminates the routine.

When the battery has not been replaced, the navigation controller 10 sets the current vehicle position as the SOC increase point in a step S404, similarly to the step S107 of the first embodiment.

In a step S405, the navigation controller 10 performs the processing of the steps S110-S113 of the first embodiment. It should be noted, however, that in the step S112, the “Battery replaced” item is not included in the capability section (5) of the items displayed on the display 40. The reason for this is that when it is determined that the battery has been replaced in the step S403 of the battery charge amount increase point registration routine according to this embodiment, battery charge amount increase point registration is not performed.

Following the processing of the step S405, the navigation controller 10 terminates the routine.

In this embodiment also, similarly to the first embodiment, the number of usable battery charge amount increase points registered in the database 20 can be increased every time the battery 60 is charged.

Furthermore, according to this embodiment, battery charge amount increase points can be identified appropriately and registered even in a vehicle installed with the vehicle-mounted charging device 80.

In the first to third embodiments, battery replacement points may be excluded from the battery charge amount increase points. Conversely, in the fourth embodiment, battery replacement points may be included in the battery charge amount increase points.

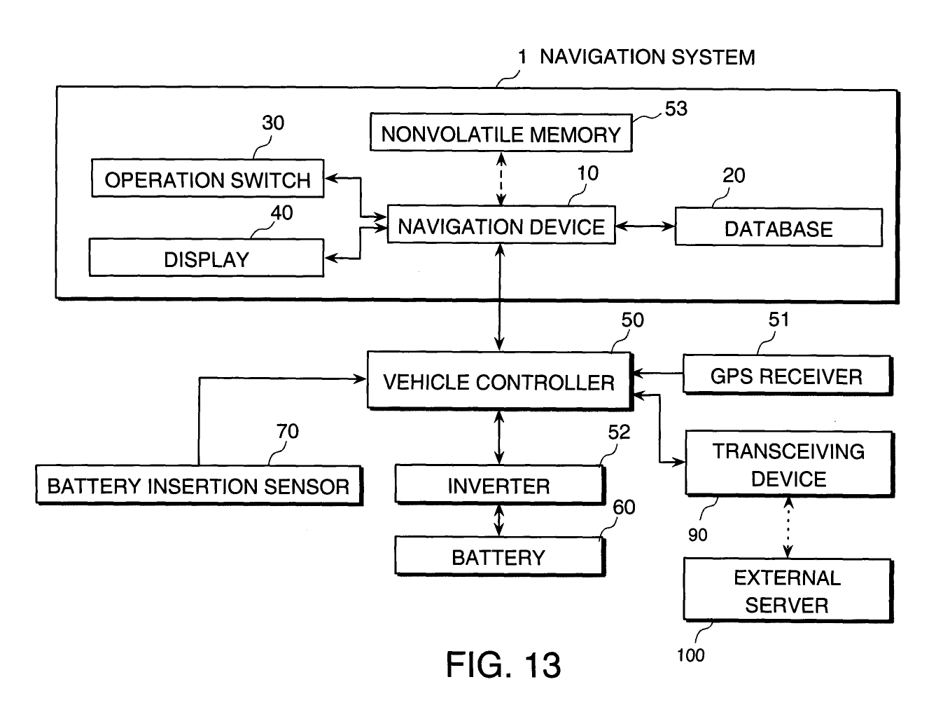

Referring to FIG. 13, a fifth embodiment of this invention will be described.

In this embodiment, the navigation system 1 includes, in addition to the navigation controller 10, the database 20, the operating switch 30, and the display 40 according to the first-fourth embodiments, a transceiving device 90 that transmits information to and receives information from an external server 100 that stores information from vehicles connected thereto via transceiving devices. By receiving a battery charge amount increase point registered in another vehicle from the external server 100 via the transceiving device and registering the received battery charge amount increase point in the database 20, the number of registered battery charge amount increase points can be increased greatly. Meanwhile, a battery charge amount increase point registered in the database 20 is transmitted to the external server and provided for use in the other vehicle.

By sharing battery charge amount increase point information in this manner, additional battery charge amount increase point registration can be performed more efficiently.

The battery charge amount increase points registered in the external server are preferably limited to locations of battery charge amount increase facilities that can be used by all users and locations of replacement battery supply facilities. Further, the battery charge amount increase points registered in the external server are preferably limited to charging points in which the charging capability is classified as “rapid charging”. To ensure the reliability of the information, the external server may disclose only battery charge amount increase points registered by a plurality of vehicles.

With respect to the above description, the contents of Tokugan 2009-152056, with a filing date in Japan of Jun. 26, 2009, and Tokugan 2010-057683, with a filing date in Japan of Mar. 15, 2010, are incorporated herein by reference.

This invention was described above using several specific embodiments, but the invention is not limited to these embodiments, and a person skilled in the art would be able to apply various amendments and modifications to the embodiments within the technical scope of the claims.

The embodiments of this invention in which an exclusive property or privilege is claimed are defined as follows:

1.-18. (canceled)

19. A battery charge amount increase facility information provision device for providing information relating to a battery charge amount increase facility to a vehicle installed with a battery that is charged using an external power supply, the battery charge amount increase facility including at least one of a battery charging facility and a battery replacement facility, comprising:
a current position sensor that detects a current position of the vehicle;
a charge amount sensor that detects a battery charge amount;
a database which registers the information relating to the battery charge amount increase facility; and
a programmable controller programmed to:
determine whether or not the battery charge amount has increased under a predetermined condition; and
register the current position of the vehicle in the database as a location of a battery charge amount increase facility when the battery charge amount has increased under the predetermined condition.

20. The battery charge amount increase facility information provision device as defined in claim 19, wherein the controller is further programmed to determine that the battery charge amount has increased under the predetermined condition when the battery charge amount has increased after the vehicle has been stationary for a predetermined amount of time.

21. The battery charge amount increase facility information provision device as defined in claim 20, further comprising a battery replacement sensor that detects replacement of the battery, wherein the controller is further programmed to register the current position of the vehicle as a battery charging facility when the battery charge amount has increased under the predetermined condition while replacement of the battery is not detected.

22. The battery charge amount increase facility information provision device as defined in claim 20, further comprising a sensor that detects a charge time of the battery and a battery replacement sensor that detects replacement of the battery, wherein the controller is further programmed to calculate, when replacement of the battery is not detected, an increase in the battery charge amount during the charge time of the battery, estimate a charging capability of the battery charge amount increase facility from the charge time of the battery and the increase in the battery charge amount, and register the current position of the vehicle as a battery charging facility together with the estimated charging capability in the database.

23. The battery charge amount increase facility information provision device as defined in claim 19, further comprising a battery replacement sensor that detects replacement of the battery, wherein the controller is further programmed to register the current vehicle position in the database as a location of a battery replacement facility when replacement of the battery is detected.

24. The battery charge amount increase facility information provision device as defined in claim 19, wherein the controller is further programmed to determine that the battery charge amount has increased under the predetermined condition when a difference between the current battery charge amount and a battery charge amount immediately before the charge amount of the battery switches from a decreasing state to an increasing state exceeds a threshold.

25. The battery charge amount increase facility information provision device as defined in claim 24, wherein the vehicle comprises a regenerative energy charging device which charges the battery using a regenerative energy generated by braking, and the threshold is set at a value exceeding an increase in the charge amount of the battery produced by the regenerative energy.

26. The battery charge amount increase facility information provision device as defined in claim 19, wherein the vehicle comprises a travel drive system that uses power supplied by the battery, and the controller is further programmed to determine that the battery charge amount has increased under the predetermined condition when the battery charge amount increases between a point at which the travel drive system switches from ON to OFF and a point at which the drive system switches from OFF to ON.

27. The battery charge amount increase facility information provision device as defined in claim 26, wherein the controller is further programmed to determine that the battery charge amount has not increased under the predetermined condition when the vehicle position at the point where the travel drive system switches from ON to OFF differs from the vehicle position at the point where the drive system switches from OFF to ON.

28. The battery charge amount increase facility information provision device as defined in claim 27, wherein the controller further comprises a non-volatile memory that stores the vehicle position and the battery charge amount at the point where the travel drive system switches from ON to OFF.

29. The battery charge amount increase facility information provision device as defined in claim 19, wherein the vehicle comprises a vehicle-mounted charging device which charges the battery, and the controller is further programmed to determine that the battery charge amount has not increased under the predetermined condition when the battery is charged by the vehicle-mounted charging device.

30. The battery charge amount increase facility information provision device as defined in claim 19, wherein the current position sensor is constituted by a receiver of a global positioning system.

31. The battery charge amount increase facility information provision device as defined in claim 19, wherein the controller is further programmed to determine whether or not the current position of the vehicle corresponds to a location of a battery charge amount increase facility registered in the database, and not to register the current position of the vehicle in the database as a location of a battery charge amount increase facility when the current position of the vehicle corresponds to a location of a battery charge amount increase facility registered in the database.

32. The battery charge amount increase facility information provision device as defined in claim 19, further comprising a display device and an input device, wherein the controller is further programmed to display the information relating to a battery charge amount increase facility registered in the database on the display device in accordance with an operation of the input device.

33. The battery charge amount increase facility information provision device as defined in claim 32, wherein the controller is further programmed to display a question on the display device inquiring whether or not to register the current position of the vehicle in the database as the location of a battery charge amount increase facility when the battery charge amount has increased under the predetermined condition, and register the current position of the vehicle in the database as the location of a battery charge amount increase facility only when a command to register the current position of the vehicle in the database as the location of a battery charge amount increase facility is input via the input device.

34. The battery charge amount increase facility information provision device as defined in claim 19, further comprising a transceiving device that transmits information to and receives information from an external server that stores information transmitted from another vehicle, wherein the controller is further programmed, when the current position of the vehicle is registered in the database as a location of a battery charge amount increase facility to transmit the location of the battery charge amount increase facility to the external server.

35. The battery charge amount increase facility information provision device as defined in claim 34, wherein the controller is further programmed to register a location of a battery charge amount increase facility that is received from the external server in the database.

36. A battery charge amount increase facility information provision device for providing information relating to a battery charge amount increase facility to a vehicle installed with a battery that is charged using an external power supply and a database that registers the information relating to the battery charge amount increase facility, the battery charge amount increase facility including at least one of a battery charging facility and a battery replacement facility, the device comprising:
means for detecting a current position of the vehicle;
means for detecting a battery charge amount;
means for determining whether or not the battery charge amount has increased under a predetermined condition; and
means for registering the current position of the vehicle in the database as a location of a battery charge amount increase facility when the battery charge amount has increased under the predetermined condition.

37. A battery charge amount increase facility information provision method for providing information relating to a battery charge amount increase facility to a vehicle installed with a battery that is charged using an external power supply and a database that registers the information relating to the battery charge amount increase facility, the battery charge amount increase facility including at least one of a battery charging facility and a battery replacement facility, the method comprising:
detecting a current position of the vehicle;
detecting a battery charge amount;
determining whether or not the battery charge amount has increased under a predetermined condition; and
registering the current position of the vehicle in the database as a location of a battery charge amount increase facility when the battery charge amount has increased under the predetermined condition.
